(19) United States
(12) Patent Application Publication
(10) Pub. No.: US 2002/0086529 A1
(43) Pub. Date: Jul. 4, 2002

(54) Actively cooled dispenser system for improved resistivity and phase control in metal CVD from organometallic precursors

(76) Inventors: Fenton Read McFeely, Ossining, NY (US); John Jacob Yurkas, Stanford, CT (US)

Correspondence Address: Richard L. Catania, Scully, Scott, Murphy & Presser, 400 Garden City Plaza, Garden City, NY, 11530, US

(21) Appl. No.: 09/753,977

(22) Filed: Jan. 3, 2001

(51) Int. Cl. H01L 21/44

(52) U.S. Cl. 438/681

(57) ABSTRACT

An apparatus and method for forming high-purity, high-conductivity metal films deposited by chemical vapor deposition (CVD) on a surface of a substrate is provided. The apparatus includes a cooling system which is in thermal contact with a precursor dispenser such that cooling is sufficiently controlled to prevent unwanted chemical impurities, i.e., non-metallic precursor byproducts, from being introduced into the deposited metal film. The apparatus and method can be used with a wide variety of metallic precursors and under most CVD reaction conditions.

### FIELD OF THE INVENTION

The present invention relates to chemical vapor deposition (CVD) of metal films from organometallic or inorganic precursors in a low-pressure reactor; and more particularly to a method and apparatus for deposition of a metal film by CVD in which the purity and phase of the deposited metal film is controlled by cooling the precursor dispenser.

### BACKGROUND OF THE INVENTION

In order to produce wiring structures for microelectronic devices, it is often desirable to deposit metallic films upon substrates of dielectric materials disposed on semiconductor substrates via chemical vapor deposition (CVD). A frequent limitation in CVD processes is the maximum temperature to which the substrate may be subjected. This limitation may arise from the inherent temperature sensitivity of the dielectric itself, e.g., when the dielectric comprises an organic material, or from the sensitivity of some other metal or insulator within the total wiring structure.

The restriction of substrates to a temperature below a certain maximum, Tₘₐₓ, may frequently constitute an obstacle to the deposition of high-purity, high-conductivity metals in a particular desired crystallographic phase. This is particularly likely in a single reagent precursor, or pyrolytic process, in which a single type of chemically reactive molecule, i.e., the precursor, containing the metal to deposited, is incident upon the surface of the heated substrate, without the co-presence of any additional chemically active reagent. Although simple, such a reaction involves the following two essential steps:

(1) The adsorption and decomposition of precursor molecules; and

(2) The desorption of non-metal byproducts of precursor decomposition, typically organic molecules or fragments thereof, back into the gas phase.

For the practical production of ‘high-purity’ metal films by such a CVD reaction, two conditions must be satisfied. The first condition is that the substrate temperature must be such that for a practical incident flux of precursor molecules, the rate of step 1 mentioned above is sufficiently high to grow films at an acceptable rate. The second condition is that the substrate temperature must be such that step 2 mentioned above proceeds at a rate sufficient to prevent the non-metal byproducts of precursor deposition being “buried” by the continuing influx of metal atoms and incorporated into the film as impurities. The essence of these two conditions is that step 2 should be “faster” than step 1.

Not surprisingly, as different chemical processes are involved, the substrate temperature dependences of step 1 and 2 are in general different. This can lead to different minimum temperatures for which condition one and condition two are satisfied. For a given set of operating conditions (precursor and carrier gas flow rates and partial pressures, pumping speed, partial pressures of background gasses and the like) let the minimum substrate temperature at which condition 1 can be satisfied be denoted as T₁, and let the minimum substrate temperature at which condition 2 can be satisfied be denoted as T₂. If, as is frequently the case, T₂>T₁, there exists a range of substrate temperatures in which films can be grown, but they will be contaminated with impurities arising from the non-metallic portions of the precursor molecules, typically carbon and oxygen.

The impurities resulting from the operation of prior CVD processes in the regime T₁<T<T₂ may reduce the functionality of the resultant films in a variety of ways. For example, the conductivity will be reduced, the films may exhibit poor mechanical properties, e.g., poor adhesion, and impurity stabilized metastable phases may be deposited, the subsequent transformation of which could result in a variety of problems. It is therefore imperative to avoid the aforementioned regime in devising a successful CVD process. The problem arises when, for a specific substrate, the maximum allowable temperature, Tₘₐₓ, falls below or only slightly above T₂. In such a case, one would be forced either to accept and “live with” contaminated films, or, in the case that Tₘₐₓ were only slightly greater than T₂, be forced to implement an extremely precise and narrow processing temperature window, which would involve difficult and costly engineering.

The critical temperature, T₂ is not constant, but depends upon both the physical design of the reactor and the processing conditions upon which the reaction is carried out. Naturally, it has been common practice to adjust the processing conditions to minimize T₂ when faced with a substrate with a low Tₘₐₓ. One trivial example of this would be to reduce the flux or precursor with the counterproductive consequence of lowering the overall deposition rate. To a point this could perhaps be tolerated, but such a measure would always reduce reactor throughput. Other process tunings might help, such as by optimizing carrier gas flow rates and pumping speeds, but it would clearly be desirable to devise an apparatus and method which would reduce T₂ by itself, and thus would offer benefits independently of, and in addition to, any which might be made by process optimization.

A schematic of a basic low-pressure CVD reactor 10, employing prior art dispensation, suitable for the deposition of metal films is shown, for example, in FIG. 1. Within a pumped vacuum chamber 12, are disposed substrate 14, heater 16, and dispenser 18, with a front surface, 20, precursor inlet line 22 and vacuum pump 24. In normal operations, the substrate is typically introduced into the pre-evacuated chamber via a transfer device, (not shown). Some time is allowed to elapse to bring the substrate to the desired deposition temperature. Then precursor gas, which might or might not be entrained in an inert carrier gas such as He or Ar, is introduced via appropriate metering valves (not shown) into the dispenser, which directs the precursor onto the substrate.

The prior art dispenser is essentially an internal chamber with a pattern of holes leading from its interior to surface 20 facing substrate 14. The walls of the dispenser might typically be constructed of any vacuum-compatible metal, such as stainless steel, aluminum, copper, or a suitable chosen copper alloy. The pattern of holes and the spacing of surface 20 from substrate 14 are chosen to distribute the precursor evenly upon the substrate, so as to ensure depositions of uniform thickness. The spacing is typically rather small, less than about 2 inches. This sort of tight spacing is generally required for uniform depositions and efficient precursor utilization. If it were spaced farther back, it would begin to look like a “point source” of precursor, and the precursor flux at the center of the substrate would exceed that at the edges, leading to non-uniform depositions. Furthermore, substantial precursor could miss the substrate entirely, leading to waste.

However, by placing dispenser front surface 20 in such close proximity to heater 16, which is typically run in an always-on-mode, surface 20 and much of dispenser 18 is heated to substantially above room temperature. It has been observed that this can be sufficient to exceed T₁ for the deposition of metal onto surface 20, resulting in substantial deposition onto this surface. The ligands or ligand fragments liberated into the gas phase via a process occurring on the dispenser surface can impinge upon the substrate during film growth where they can be incorporated into the deposited film with the aforementioned deleterious effects on film properties.

In view of the drawbacks mentioned hereinabove for prior art CVD apparatuses and CVD methods, there is a continued need to provide a new and improved apparatus and method of depositing a high-purity, high-conductive metal film onto a surface of a substrate.

### SUMMARY OF THE INVENTION

The present invention provides an apparatus and method to lower the value of T₂, defined above, for CVD processes, so as to produce purer deposited metallic films at lower temperatures and at higher rates of deposition than would otherwise be possible. As secondary benefits, the inventive apparatus and method substantially reduce precursor waste, which can be expensive, and particulate contaminants both of which help to reduce the frequency at which the reactor must be cleaned, increasing overall processing efficiency.

In one aspect of the present invention, an improved method for depositing high-purity metal films is provided. Specifically, the method of the present invention comprises the steps of:

(a) providing a substrate having a surface requiring at least one metal film thereon;

(b) positioning said substrate in a chemical vapor deposition reactor chamber, said reactor chamber including at least a precursor dispenser having a front surface facing said substrate, a cooling system in thermal contact with said precursor dispenser and a heater, said substrate being placed between said precursor dispenser and said heater; and

(c) depositing a metallic precursor onto said surface of said substrate utilizing a chemical vapor deposition process in which precursor molecules from said precursor dispenser are distributed onto said substrate while cooling said precursor dispenser so as to maintain temperature of at least the front surface of said precursor dispenser below that necessary to decompose said precursor molecules that flow through said dispenser.

The inventive method provides high-purity, high-conductivity metal films using lower substrate temperatures than heretofore possible utilizing prior art CVD deposition. Moreover, the inventive method is capable of providing a selected phase of material, which is oftentimes difficult, if not impossible, to obtain utilizing prior art CVD processes.

In accordance with the present invention, the temperature is controlled by utilizing a cooling system which is in thermal contact with the CVD precursor dispenser. The term “thermal contact” is used herein to mean at a distance which is either in direct contact with the precursor dispenser or in close proximity to the precursor dispenser, i.e., at distance of from about 1 cm or less. The cooling system may completely or partially surround the dispenser, or it may be positioned to shield the dispenser from sources of heat.

In another aspect of the present invention, an improved CVD apparatus which is capable or providing higher-purity CVD deposited metal films, while controlling the phase of the deposited metal film is provided. Specifically, the inventive apparatus comprises:

a reactor chamber housing at least a precursor dispenser having at least a front surface and a cooling system for said precursor dispenser, wherein said precursor dispenser includes at least a metallic precursor and said cooling system is in thermal contact with said precursor dispenser so as to sufficiently suppress deposition of said metallic precursor on said dispenser front surface whereby metal films grown on said substrate have substantially no non-metallic precursor byproducts.

The types of cooling systems that are employed in the present invention include, but are not limited to: fully-jacketed cooling systems which include a refrigerant; a thermal conductive material; a cooled, semi-opened thermal shield, and other like cooling systems.

### BRIEF DESCRIPTION OF THE DRAWINGS

FIG. 1 is a schematic of a prior art low-pressure CVD reactor without a means for cooling the metal precursor.

FIG. 2 is a schematic of the inventive low-pressure CVD reactor which includes a fully-jacketed cooling system in thermal contact with a precursor dispenser.

FIG. 3 is a schematic of the inventive low-pressure CVD reactor which includes a thermal conductive plate as a cooling system.

FIG. 4 is a schematic of the inventive low-pressure CVD reactor which includes a cooled, semi-opened thermal shield between the precursor dispenser and the substrate.

### DETAILED DESCRIPTION OF THE INVENTION

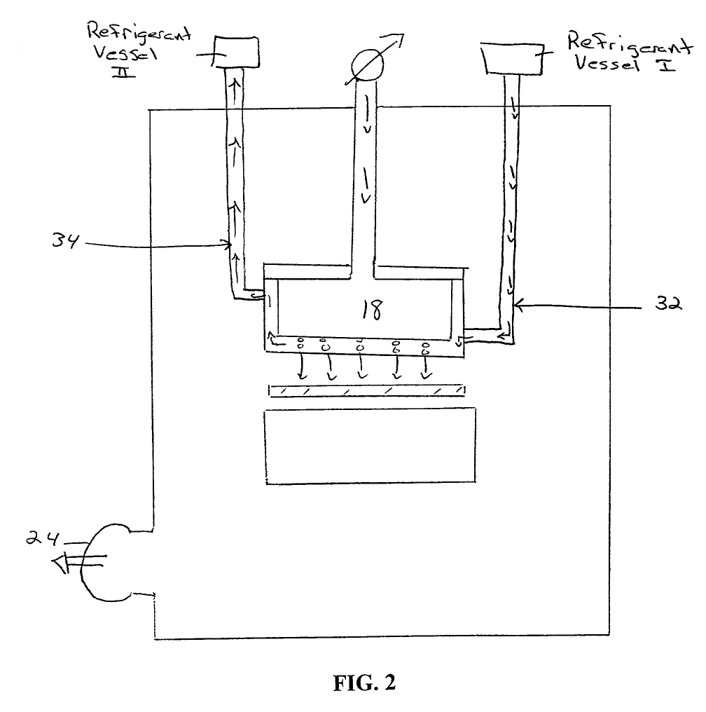

The present invention which provides a new and improved CVD apparatus and method for depositing high-purity metal films from the inventive CVD apparatus will now be described in greater detail be referring to FIGS. 2-4.

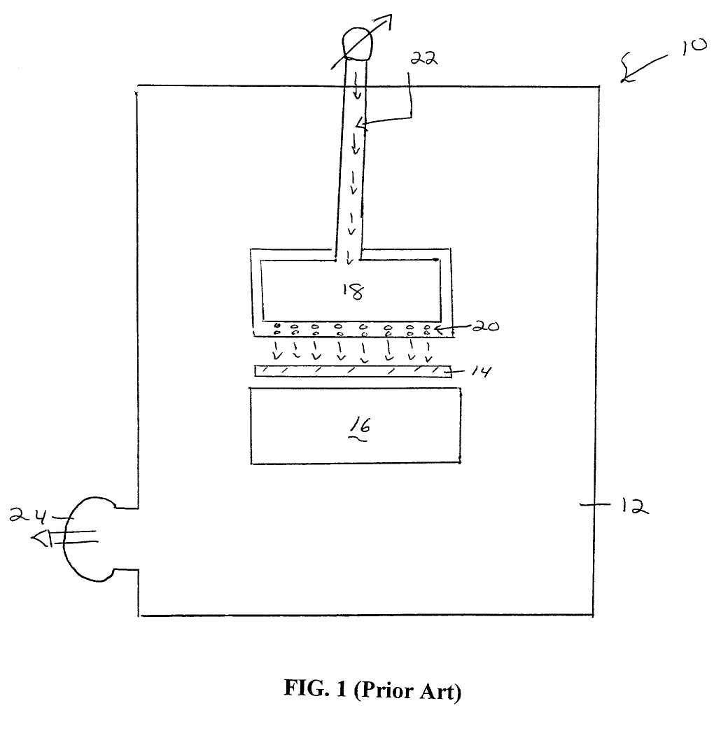

Broadly speaking, in the present invention, a dynamic temperature regulation system, (i.e., cooling system) to be described in more detail below, is employed and is positioned so as to be in thermal contact with a precursor dispenser of a CVD apparatus so as to cool the dispenser, especially the dispenser front surface. The inventive apparatus including one type of cooling system that may be employed in the present invention is shown in FIG. 2. In the present invention, the front and sidewalls of the dispenser have been modified to incorporate a refrigerant reservoir, 30, with inlet and outlet lines 32 and 34 respectively. It is noted that in FIG. 2, like reference numerals are employed for describing like and corresponding elements shown in FIG. 1.

With suitable standard liquid refrigerant handling and delivery and control systems, it is possible to thermostatically regulate the temperature of front surface 20 of dispenser 18 at a temperature substantially lower than is possible employing the system of FIG. 1. In accordance with the present invention, the refrigeration system may include any type of refrigerant that is commonly employed in such systems. That is, there is no particular restriction on the refrigerant. One type of refrigerant that can be employed in the present invention is a liquid such as filtered tap water. Another type of refrigerant that can be employed in the present invention is a compressed gas.

Although specifics are given for the above cooling system, any method which is capable of sufficiently cooling precursor molecules that flow through the precursor dispenser may be employed in the present invention. The cooling of surfaces with which precursor molecules may come into contact with while flowing through the precursor dispenser is critical since it prevents formation and incorporation of decomposition precursor byproducts which may be incorporated into the resultant film. In accordance with the present invention, formation of decomposition byproducts in the example given below, W CVD by W(CO)₆, can be achieved by maintaining dispenser front surface 20 at a temperature below about 100° C. Requisite front surface dispenser temperatures for other CVD processes will vary depending on the specifics of the chemistry of the processes.

It should be noted that the CVD process employed in the present invention includes the use of conventional materials and conditions that are typically employed in the prior art. The improvement provided herein is the use of the inventive cooling system, which is in thermal contact with the precursor dispenser. Thus, the present invention is not limited to specific types of precursors or CVD reaction conditions. Instead, a wide variety of precursors and CVD reaction conditions that are well known to those skilled in the art can be employed in the present invention.

For example, the precursor employed in the present may include any number of metallic precursor compounds or complexes which are capable of forming a metallic film (including multilayers) on a surface of a substrate by CVD. Thus, the present invention contemplates the use of a wide variety of precursors which may comprise an organometallic compound or complex, an inorganic compound or complex, or mixtures and combinations thereof. Some examples of suitable precursors that can be employed in the present invention include, but are not limited to: metal carbonyls or derivatives thereof; metal halides; metal alkyls; metal allyls; metal diketonates and other like metal-containing inorganic or organometallic compounds or complexes In one highly preferred embodiment of the present invention, the precursor is W(CO)₆.

The precursor may be employed neat or it may be admixed with one or more co-reactants such as hydrogen. Additionally, the precursor may also be admixed with an inert gas such as He or Ar. The amounts of the various components present in the precursor may vary and are not critical to the operation of the present invention.

As stated above, the CVD method of the present invention is also not limited to any specific deposition reaction conditions. Therefore, all suitable CVD reaction conditions well known to those skilled in the art may be employed herein. Typically, the deposition is carried out at temperatures below about 500° C. Some illustrative reaction conditions that can be employed in the present invention, include, but are not limited to:

Reactor Base Pressure: about 10⁻⁸ Torr.

Deposition Reactor Pressure: about 10 to about 300 mTorr.

Precursor and Inert Gas Flow rate: about 100 to 1000 sccm.

Substrate Temperature: about 370° C. to about 430° C.

It is again emphasized that the above CVD reaction conditions are exemplary, and by no ways limit the invention.

In the present invention, the substrate in which the metal film is to be formed is also not limited. Thus any substrate in which a metallic film can be formed thereon can be employed in the present invention. For example, the substrate employed in the present invention may be composed of semiconductor materials such as Si, Ge, Ga, SiGe, GaAs, InP, InAs, another III/NV compound semiconductors; layered semiconductors such as Si/SiGe; silicon-on-insulators (SOIs); dielectric materials including organic and inorganic dielectrics; diffusion barrier layers such as WN; polysilicon; or other metallic films.

The inventive method thus finds a wide range of applications including, but not limited to: use in fabricating transistors including complementary metal oxide semiconductor (CMOS), field effect transistors (FETs); resistors; capacitors; memory cells (including gate conductors, wordlines and bitlines); wiring structures (including metallic vias and lines), interconnect structures (including metallic vias and lines) and other like applications in which a deposited metal film is required.

The operative chemical mechanism whereby the improved delivery system produces superior films is quite simple to apprehend, and leads to the conclusion that it will prove generally beneficial in CVD reactions involving organometallic precursors. The growth of pure metal films depends critically upon the ability of the growing surface to desorb potential impurities faster than they can be buried and incorporated by the continuing buildup of metal atoms. An unavoidable source of such potential impurity atoms are ligands (or fragments of ligands) of the precursor molecules which dissociate on the substrate itself. However, other sources are also possible, principally from the ligands or ligand fragments of precursor molecules which have decomposed upon other hot surfaces in the reactor, especially on a hot dispenser front surface.

Decomposition of precursor molecules on this surface will be accompanied by the liberation of impurity-precursor species (carbon monoxide molecules in the case of the specific example above) into the gas phase, where they have a direct line-of-sight path to the substrate. This will add to the concentration of impurity precursor species present on the growth surface and increase the impurity incorporation rate, degrading the film properties. The decomposition of precursor on the dispenser front surface, which is prevented herein, has exactly the same deleterious effect as deliberately introducing impurities into the precursor stream. Seen in this light, it is clear that the operation of the dispenser with an active cooling system should almost always be helpful, and never harmful, in the effort to produce high purity metal films.

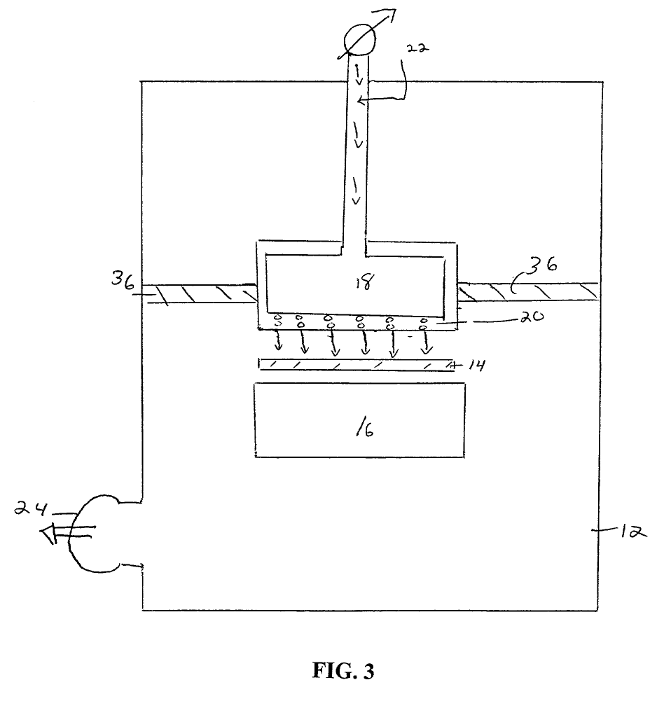

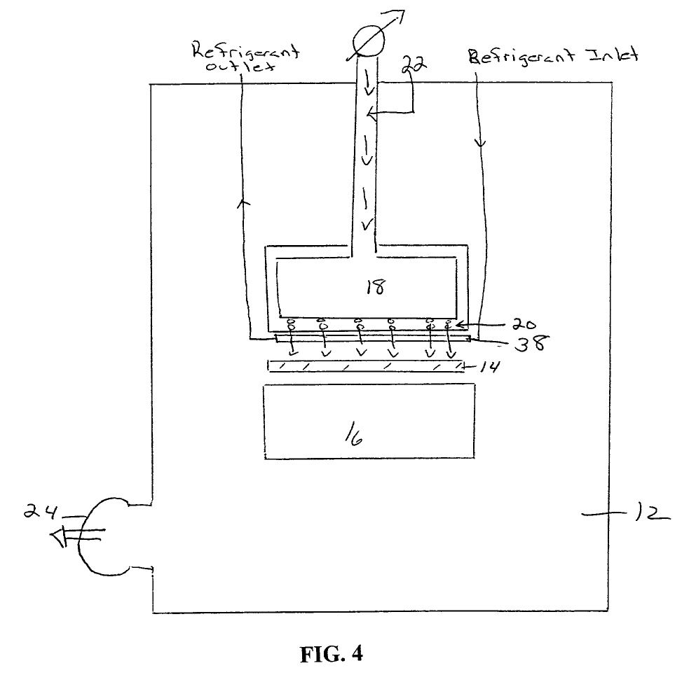

Naturally, different reactions would be expected to exhibit variations in their sensitivity to excess impurities in the reactant stream. In addition, various applications for the deposited films could vary in their tolerances for impurities in the films. Accordingly, in addition to the fully-jacketed cooling system depicted in FIG. 2, the basic idea of the present invention could be realized in alternative, simpler ways. For instance, the front surface of the dispenser might not need to be directly refrigerated, as in FIG. 2, but could be a solid plate of high-thermal conductivity material, such as aluminum or copper, and could merely be heat-sink to a suitably thermostatted reservoir via a high-thermal conductivity link. This is illustrated in FIG. 3. Also, the requisite suppression of unwanted precursor degradation could be achieved by the introduction of a suitably cooled, semi-opened thermal shield between an uncooled dispenser and the substrate, as illustrated in FIG. 4.

The following example is given to illustrate some of the advantages that may be obtained utilizing the inventive CVD apparatus and CVD deposition process.

### EXAMPLE

The efficacy of the cooled dispenser system of the present invention was tested and employed in the context of W metal deposition from W(CO)₆ onto substrates comprising SiO₂ overlayers on Si substrates. This system is particularly sensitive to contamination and conductivity degradation when the reaction is performed at a substrate temperature of less than about 400° C. Moreover, an undesirable impurity stabilized metastable phase, beta-W, can be formed as a result of contamination, instead of the preferred, stable alpha-W.

A CVD system, schematically depicted in FIG. 2 was used for the tests. A substrate comprising a silicon dioxide overlayer on a silicon substrate was placed into position atop the heater in the deposition chamber via a vaccum transfer device. The CVD chamber exhibited a base pressure of less than about 1×10⁻⁷ torr. The substrate was allowed to heat to about 390° C. The cooled dispenser was as depicted in FIG. 2, and was constructed of type 304 stainless steel though out, with both the front surface 20 and the sidewalls covered by the cooling jacket/refrigerant reservoir. The dispenser and heater both had a diameter of about 8″, and the total volume of the refrigerant reservoir was approximately 1 liter. Water was employed for the refrigerant, and was flowed at approximately 4 liters/min.

Under such conditions, the dispenser front surface temperature was estimated to be less than about 50° C. (it is again noted that any temperature of less than about 100° C. is sufficient in the present invention). The deposition was performed by admitting a mixture of Ar and W(CO)₆ into the system through the precursor inlet tube via an external bubbler apparatus. Ar flow as approximately 300 SCCM. Under these conditions, the total pressure during the deposition was approximately 45 mtorr and the partial pressure of W (CO)₆ was approximately 2 mtorr, which yielded a growth rate of about 10 nm/min. Under these conditions, 100 nm W films were grown with an average resistivity of less than about 50 microohm-cm, and were shown by x-ray diffraction analysis to be pure alpha-phase. With this system it proved possible to produce pure alpha-phase material at substrate temperatures as low as about 370° C. Under long-term operation, there was negligible W deposition on dispenser surface 20.

### Comparative Example

To simulate the effects of an un-cooled dispenser, the above procedure was repeated, but the system was modified by placing a perforated aluminum plate between the showerhead and the substrate. This plate was positioned at about 1/4″ above front surface 20, to which it was attached by a weak thermal link. This plate rose to approximately 180° C. during deposition, accurately simulating the uncooled front surface 20 of a dispenser constructed as in FIG. 1. Test samples run with this uncooled surface plate in place but with otherwise identical procedures to the above example showed markedly higher resistivity, averaging about 127 microohm-cm. Moreover, x-ray diffraction analysis revealed that such films were predominately in the metastable beta-phase.

Using the prior art configuration, it was impossible to produce pure alpha-phase material at a substrate temperature of less than about 420° C. Moreover substantial W buildup was quickly observed on the simulated front surface plate. This material had noticeably bad adhesion and was observed to flake off readily, making it a source of particulate contamination. This problem was entirely eliminated by employing the cooled dispenser as above.

The following conclusions were drawn for the above example and comparative example: The cooled dispenser effectively reduced T₂ for the growth of pure alpha-W films by approximately 50° C., a substantial advantage; in constant temperate comparisons the properly cooled dispenser system always gave CVD deposited metallic films of superior conductivity. The cooled dispenser dramatically reduced an important source of particulate contamination, deposition on the dispenser. By substantially eliminating deposition on or within the dispenser, the utilization efficiency of the precursor is obviously enhanced. The operation of cooled dispensing system is clearly compatible with all of the same processing optimizations to which the CVD reaction may be subject.

While the present invention has been particularly shown and described with respect to preferred embodiments thereof, it will be understood by those skilled in the art that the foregoing and other changes in form and detail may be made without departing from the spirit and scope of the present invention. It is therefore intended that the present invention not be limited to the exact forms and details described and illustrated, but fall within the scope of the appended claims.

Having thus described our invention in detail, what we claim as new and desire to secure by the Letters Patent is:

1. A method of forming a high-purity metal film on a surface of substrate comprising the steps of:
(a) providing a substrate having a surface requiring at least one metal film thereon;
(b) positioning said substrate in a chemical vapor deposition reactor chamber, said reactor chamber including at least a precursor dispenser having a front surface facing said substrate, a cooling system in thermal contact with said precursor dispenser and a heater, said substrate being placed between said precursor dispenser and said heater; and
(c) depositing a metallic precursor onto said surface of said substrate utilizing a chemical vapor deposition process in which precursor molecules from said precursor dispenser are distributed onto said substrate while cooling said precursor dispenser so as to maintain temperature of at least the front surface of said precursor dispenser below that necessary to decompose said precursor molecules that flow through said dispenser.

2. The method of claim 1 wherein said substrate is selected from the group consisting of a semiconductor material, a layered semiconductors, a silicon-on-insulator, a dielectric material, a diffusion barrier and a metallic film.

3. The method of claim 1 wherein said substrate is a semiconductor material selected from the group consisting of Si, Ge, Ga, SiGe, GaAs, InP, InAs and other IIII/V semiconductors.

4. The method of claim 1 wherein said substrate includes silicon dioxide formed on Si.

5. The method of claim 1 wherein said substrate includes an organic dielectric formed on Si.

6. The method of claim 1 wherein said metallic precursor is selected from the group consisting of organometallic compounds or complexes, inorganic compounds or complexes and mixtures or combinations thereof.

7. The method of claim 1 wherein said metallic precursor is a metal carbonyl, a metal halide, a metal alkyl, a metal allyl or metal diketonate.

8. The method of claim 1 wherein said metallic precursor is W(CO)₆.

9. The method of claim 1 wherein metallic precursor is admixed with one or more co-reactants.

10. The method of claim 1 wherein said metallic precursor is admixed with an inert gas.

11. The method of claim 1 wherein said chemical vapor deposition process is carried out at a reactor base pressure of about 10⁻⁸ Torr.

12. The method of claim 1 wherein said chemical vapor deposition is carried out at a temperature of less than 500° C.

13. The method of claim 1 wherein said cooling system is a fully-jacketed cooling system.

14. The method of claim 13 wherein said fully-jacketed cooling system includes a refrigerant.

15. The method of claim 14 wherein said refrigerant is a liquid or a compressed gas.

16. The method of claim 1 wherein said cooling system includes a thermal conductive material.

17. The method of claim 16 wherein said thermal conductive material is composed of aluminum or copper.

18. The method of claim 1 wherein said cooling system is a cooled, semi-opened thermal shield.

19. The method of claim 1 wherein said non-metallic precursor by product includes CO molecules.

20. A method of forming alpha-phase W on a surface of a substrate, said method comprising the steps of:
(a) providing a substrate having a surface requiring at least one W film thereon;
(b) positioning said substrate in a chemical vapor deposition reactor chamber, said reactor chamber including at least a precursor dispenser having a front surface facing said substrate, a cooling system in thermal contact with said precursor dispenser and a heater, said substrate being placed between said precursor dispenser and said heater; and
(c) depositing a W-containing precursor onto said surface of said substrate utilizing a chemical vapor deposition process in which W precursor molecules from said precursor dispenser are distributed onto said substrate while cooling said precursor dispenser so as to maintain temperature of at least said front surface of said precursor dispenser below that necessary to decompose said W precursor molecules that flow through said dispenser.

21. A method of forming an alpha-phase W film on a surface of a substrate, said method comprising the steps of:
(a) providing a substrate having a surface requiring at least one W film thereon;
(b) positioning said substrate in a chemical vapor deposition reactor chamber, said reactor chamber including at least a precursor dispenser having a front surface facing said substrate, a cooling system in thermal contact with said precursor dispenser and a heater, said substrate being placed between said precursor dispenser and said heater; and
(c) depositing W(CO)₆ onto said surface of said substrate utilizing a chemical vapor deposition process in which W(CO)₆ molecules from said precursor dispenser are distributed onto said substrate while cooling said precursor dispenser so as to maintain temperature of at least the front surface of said precursor dispenser below 100° while maintaining temperature of said substrate between 370° C. and 430° C.

22. An apparatus comprising a reactor chamber housing at least a precursor dispenser having a plurality of surfaces and a cooling system for said precursor dispenser, wherein said precursor dispenser includes at least a metallic precursor and said cooling system is in thermal contact with said precursor dispenser so as to sufficiently suppress deposition of said metallic precursor on said dispenser surfaces whereby metal films grown on a substrate have substantially no non-metallic precursor byproducts.

23. The apparatus of claim 22 wherein said cooling system is a fully-jacketed cooling system.

24. The apparatus of claim 23 wherein said fully-jacketed cooling system includes a refrigerant.

25. The apparatus of claim 24 wherein said refrigerant is a liquid or a compressed gas.

26. The apparatus of claim 22 wherein said cooling system includes a thermal conductive material.

27. The apparatus of claim 26 wherein said thermal conductive material is composed of aluminum or copper.

28. The apparatus of claim 22 wherein said cooling system is a cooled, semi-opened thermal shield.

29. The apparatus of claim 22 further comprising a vacuum pump connected to said reactor chamber.

30. The apparatus of claim 22 wherein said substrate positioned in close proximity to said precursor dispenser.

31. The apparatus of claim 22 further comprising precursor inlet lines that are connected to said precursor dispenser and lead to a vessel holding said precursor outside of said reactor chamber.
